(19) United States
(12) Patent Application Publication
(10) Pub. No.: US 2026/0179674 A1
(43) Pub. Date: Jun. 25, 2026

(54) MEMORY SYSTEM

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventor: Tetsuro TAKIZAWA, Nisshin-shi (JP)

(21) Appl. No.: 19/427,869

(22) Filed: Dec. 19, 2025

(30) Foreign Application Priority Data
Dec. 23, 2024 (JP) 2024-226196

(51) Int. Cl. G11C 11/406; G11C 11/4076; G11C 11/408

(52) U.S. Cl. CPC G11C 11/40618; G11C 11/4076; G11C 11/4087

(57) ABSTRACT

A memory system includes a memory controller configured to issue a precharge command to a semiconductor memory device. The precharge command includes an extension flag field to specify a processing timing of a second bank relative to a first bank to precharge the first bank and the second bank belonging to different bank groups, and a bank address field. The semiconductor memory device precharges the first bank determined by the bank address field, and precharges the second bank having a bank address obtained by inverting an inversion target bit in the bank address field at the processing timing.

### CROSS REFERENCE TO RELATED APPLICATION

This application is based on Japanese Patent Application No. 2024-226196 filed on Dec. 23, 2024, the disclosure of which is incorporated herein by reference.

### TECHNICAL FIELD

The present disclosure relates to a memory system.

### BACKGROUND

A double data rate DDR4 or a low power double data rate LPDDR5 having plural bank groups is often used as semiconductor memory device.

### SUMMARY

According to one aspect of the present disclosure, a memory system includes: a semiconductor memory device having a plurality of bank groups; and a memory controller configured to issue a command in response to an access request to the semiconductor memory device from an arithmetic device that accesses the semiconductor memory device. The memory controller issues a precharge command to the semiconductor memory device. The precharge command includes: (i) an extension flag field which is a bit string that specifies whether to precharge one bank, precharge all banks, or precharge two banks that belong to different bank groups, and (ii) a processing timing of a second bank relative to a first bank when precharging the first bank and the second bank; and a bank address field which is a bit string that specifies a bank address of a bank to be precharged. When the precharge command specifies that two banks are to be precharged, the semiconductor memory device performs a precharge on a first bank specified by the bank address field, and performs a precharge on a second bank at the processing timing specified by the extension flag field. The second bank may be specified by a bank address obtained by inverting an inversion target bit of the bank address field, and the inversion target bit may be a predetermined one bit in a bit string that specifies a bank group.

### BRIEF DESCRIPTION OF DRAWINGS

FIG. 1 is a block diagram showing a schematic configuration of a memory system according to a first embodiment.

FIG. 2 is a flowchart showing a procedure of a precharge process.

FIG. 3 is an explanatory diagram showing a data format of a precharge command in the first embodiment.

FIG. 4 is an explanatory diagram showing contents of extension flag fields in precharge commands.

FIG. 5 is a flowchart showing a procedure of a refresh process.

FIG. 6 is an explanatory diagram showing a data format of a refresh command in the first embodiment.

FIG. 7 is an explanatory diagram showing contents of extension flag fields in refresh commands.

FIG. 8 is a timing chart showing an example of operation by the memory system in the first embodiment and a comparative example.

FIG. 9 is a timing chart showing another example of operation by the memory system in the first embodiment.

FIG. 10 is a block diagram showing a schematic configuration of a memory system according to a second embodiment.

FIG. 11 is an explanatory diagram showing an example of setting in an extension flag field, a first register, and a second register in the second embodiment.

### DETAILED DESCRIPTION

A double data rate DDR4 or a low power double data rate LPDDR5 having plural bank groups is often used as semiconductor memory device. In such a semiconductor memory device, when active commands are issued consecutively to two banks belonging to different bank groups, the interval to be provided between the issuances of the two active commands can be shortened. Therefore, an active command and a read/write command can be issued consecutively without creating an empty cycle on the command bus.

However, when an active command and a read/write command are issued consecutively, a free cycle of the command bus for issuing a refresh command or a precharge command is reduced. If the issuance of an active command and a read/write command is postponed in order to issue a refresh command or a precharge command, the data access performance of the semiconductor memory device may be degraded. Therefore, a technique is desired that allows efficient use of the command bus while ensuring the timing for issuing a refresh command or precharge command.

According to one aspect of the present disclosure, a memory system includes: a semiconductor memory device having a plurality of bank groups; and a memory controller that issues a command in response to an access request to the semiconductor memory device from an arithmetic device that accesses the semiconductor memory device. In the memory system, the memory controller issues a precharge command to the semiconductor memory device. The precharge command includes: (i) an extension flag field which is a bit string that specifies whether to precharge one bank, precharge all banks, or precharge two banks that belong to different bank groups, and (ii) a processing timing of a second bank relative to a first bank when precharging two banks; and a bank address field which is a bit string that determines a bank address of a bank to be precharged. When the precharge command specifies that two banks are to be precharged, the semiconductor memory device performs a precharge on a first bank specified by the bank address field, and performs a precharge on a second bank at the processing timing specified by the extension flag field. The second bank may be specified by a bank address obtained by inverting an inversion target bit of the bank address field, and the inversion target bit may be a predetermined one bit in a bit string that specifies a bank group.

According to this type of memory system, when a precharge command specifies that two banks are to be precharged, one precharge command can precharge two banks, e.g., the first bank and the second bank, thereby suppressing the issuance of precharge command to create space on the command bus. This allows the command bus to be used efficiently while ensuring the timing for issuing the precharge command.

According to another aspect of the present disclosure, a memory system includes: a semiconductor memory device having a plurality of bank groups; and a memory controller that issues a command in response to an access request to the semiconductor memory device from an arithmetic device that accesses the semiconductor memory device. In the memory system, the memory controller issues a refresh command to the semiconductor memory device. The refresh command includes: an extension flag field which is a bit string that specifies (i) whether to refresh all banks or refresh two banks that belong to different bank groups, and (ii) a processing timing of a second bank relative to a first bank when refreshing two banks; and a bank address field which is a bit string that determines a bank address of a bank to be refreshed. The semiconductor memory device is configured to execute, when the refresh command specifies that two banks are to be refreshed, a refresh on a first bank determined by the bank address field, and a refresh on a second bank at the relative processing timing specified by the extension flag field. The second bank is specified by a bank address obtained by inverting an inversion target bit of the bank address field, the inversion target bit being a predetermined one bit in a bit string that specifies a bank group.

According to this type of memory system, when a refresh command specifies that two banks are to be refreshed, one refresh command can refresh both the first bank and the second bank, thereby suppressing the issuance of refresh command to create space on the command bus. This allows the command bus to be used efficiently while ensuring the timing for issuing the refresh command.

### First Embodiment

### A1. System Configuration

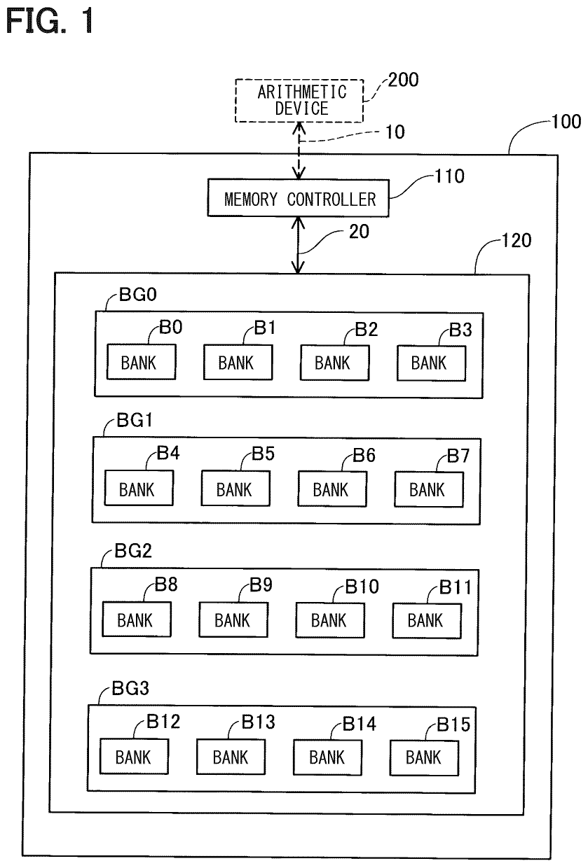

As shown in FIG. 1, a memory system 100 of a first embodiment includes a memory controller 110 and a semiconductor memory device 120. The memory system 100 reads and writes data from and to the semiconductor memory device 120 via the memory controller 110 in response to an access request issued by an arithmetic device 200. The arithmetic device 200 corresponds to, for example, a CPU or a GPU (Graphics Processing Unit).

The memory controller 110 is connected to the arithmetic device 200 via a bus 10 and receives an access request to the semiconductor memory device 120 issued by the arithmetic device 200. The memory controller 110 is connected to the semiconductor memory device 120 via a command bus 20, and issues a command represented by a bit string to the semiconductor memory device 120 in response to an access request. The memory controller 110 issues commands in accordance with a clock signal that is the basis for the operation of the memory system 100. In addition, the memory controller 110 converts the logical address of data to be accessed, which is included in commands such as read, write, and active, into a physical address that indicates the storage area on the semiconductor memory device 120 where the data is stored.

Specifically, when the access request is a write access request requesting the writing of data to the semiconductor memory device 120, the memory controller 110 issues a write command to the semiconductor memory device 120 instructing it to write data to the address specified in the access request (hereinafter referred to as “access target address”). Furthermore, when the access request is a read access request requesting reading of data from the semiconductor memory device 120, the memory controller 110 issues a read command to the semiconductor memory device 120 instructing it to read data from the access target address. The write command and the read command each include a column address portion that specifies a column address of address to be accessed.

Before issuing a write command or a read command to the semiconductor memory device 120, the memory controller 110 issues an active command to the semiconductor memory device 120 to make the semiconductor memory device 120 accessible (hereinafter referred to as “active”). The active command includes a bank number designation section, a bank address section, and a row address section.

Furthermore, in this embodiment, the memory system 100 includes a DRAM (Dynamic Random Access Memory) that complies with the so-called LPDDR5 standard. A precharge command and a refresh command can be issued as access request. The precharge command requests the execution of a “precharge”, which is an operation of turning off the FET switches between all bit lines and the capacitors of each memory cell and charging the bit lines to Vdd/2. The refresh command requests the execution of a “refresh,” which is an operation of injecting charge into the capacitor of each memory cell at regular intervals to replenish the charge that leaks from the capacitor and maintain the stored information.

The semiconductor memory device 120 is formed by arranging memory cells, which are storage elements, in a matrix, and is capable of performing various operations such as writing data to each memory cell, reading data from each memory cell, precharging, and refreshing in response to commands issued by the memory controller 110. As described above, the semiconductor memory device 120 of this embodiment is LPDDR5, and includes bank groups BG0 to BG3. The bank groups BG0 to BG3 each include four banks. The bank group BG0 includes banks B0 to B3. The bank group BG1 includes banks B4 to B7. The bank group BG2 includes banks B8 to B11. The bank group BG3 includes banks B12 to B15.

In the semiconductor memory device 120, the memory controller 110 issues a precharge command and a refresh command to the semiconductor memory device 120. A predetermined time called tRP is defined as the minimum period from when a precharge command is issued until the next precharge command is issued. Further, a refresh command is issued at predetermined intervals called tREFi. Furthermore, the minimum period from the completion of the precharge operation to the start of the refresh operation is preset. The memory controller 110 issues a precharge command and a refresh command to the semiconductor memory device 120 according to these set periods. When the semiconductor memory device 120 receives the precharge command, a precharge process is executed. When the semiconductor memory device 120 receives a refresh command, a refresh process is executed.

### A2. Precharge Process

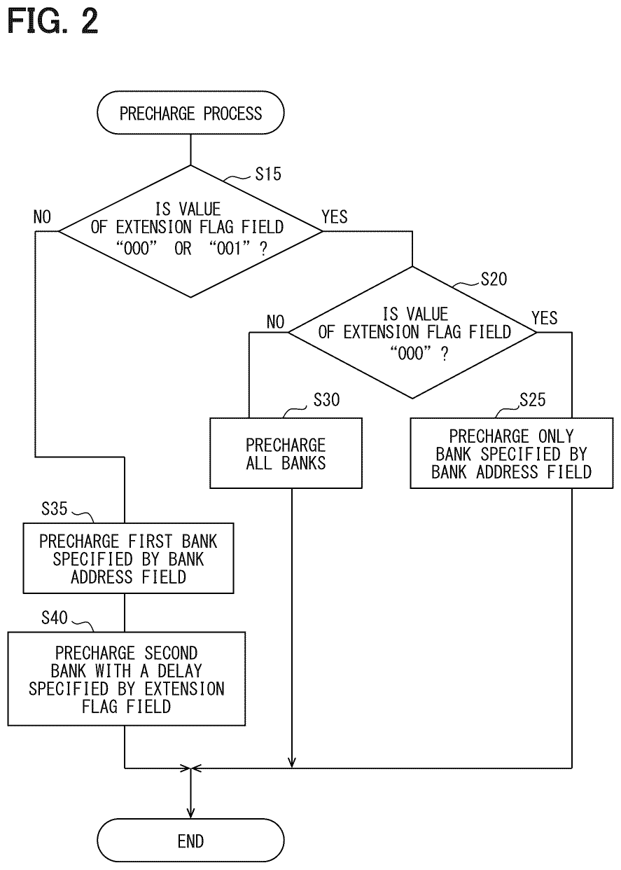

The precharge process shown in FIG. 2 is set for executing a precharge in the semiconductor memory device 120, and is executed when a precharge command is received from the memory controller 110.

The semiconductor memory device 120 determines whether the value of extension flag field of the received precharge command is “000” or “001” (step S15). Hereinafter, “step S” will be simply referred to as “S”.

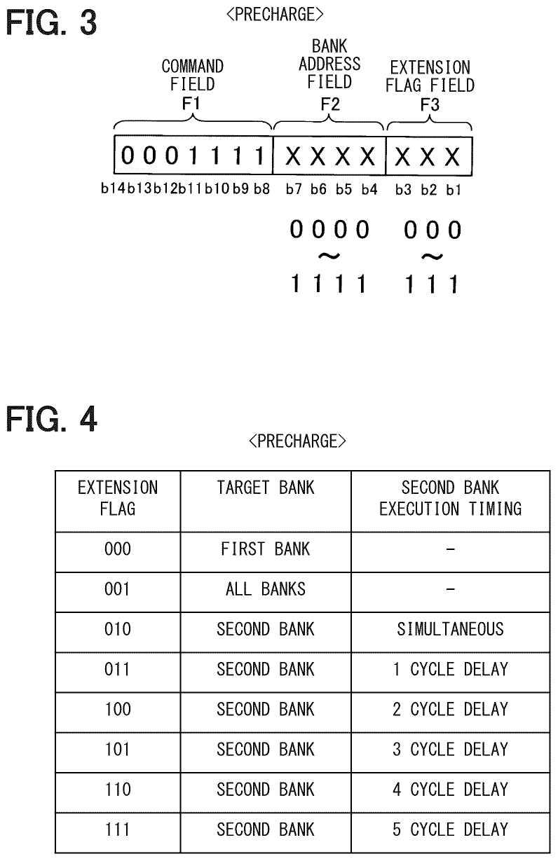

As shown in FIG. 3, the precharge command of this embodiment includes a command field F1, a bank address field F2, and an extension flag field F3. The command field F1 indicates the type of command, and is made up of a total of 7 bits, bits b8 to b14. “0001111” shown in FIG. 3 indicates a precharge command. The bank address field F2 indicates a bank and consists of four bits b4 to b7. The bank address field F2 of “0000” indicates the bank B0, and “1111” indicates the bank B15.

The extension flag field F3 indicates the number of banks to be precharged and the time difference when two banks are precharged, and is made up of bits b1 to b3. More specifically, the extension flag field F3 specifies (i) precharging one bank, precharging all banks, or precharging two banks that belong to different bank groups, and (ii) the execution timing of the second bank relative to the first bank when precharging two banks.

FIG. 4 shows a specific example of setting the extension flag field F3 in the precharge command. The following explains the contents set for each value from “000” to “111.”

“000” indicates that the bank to be precharged is only one bank specified in the bank address field F2, and (ii) is not applicable, so no specific value is set.

“001” indicates that all banks are to be precharged. In this case, the bank address specified in the bank address field F2 becomes invalid. As with “000”, “001” does not apply to (ii), so no specific value is set for “001”.

“010” indicates that two banks are to be precharged, and the relative processing timing in (ii) indicates that the processing is simultaneous, that is, that two banks are precharged simultaneously.

“011” indicates that two banks are to be precharged, and the relative processing timing in (ii) is delayed by one cycle from the execution of precharge on the first bank. The cycle means a period in clock cycles.

“100” indicates that two banks are to be precharged, and the relative processing timing in (ii) is delayed by two cycles from the execution of precharge on the first bank.

“101” indicates that two banks are to be precharged, and the relative processing timing in (ii) is delayed by three cycles from the execution of precharge on the first bank.

“110” indicates that two banks are to be precharged, and the relative processing timing in (ii) is delayed by four cycles from the execution of precharge on the first bank.

“111” indicates that two banks are to be precharged, and the relative processing timing in (ii) is delayed by five cycles from the execution of precharge on the first bank.

The bits b1 to b3 of the extension flag field F3 have the same meaning as the least significant three bits in the precharge command in the conventional LPDDR5. That is, conventionally, when the lowest three bits are “000”, this means that only one bank specified by the bank address is to be precharged. Also, when the lowest three bits are “001”, this means that all banks are to be precharged. Therefore, the purpose of using the least significant three bits is the same as in the previous system, and therefore compatibility is maintained. The two banks that are the target of precharging when the extension flag field F3 is “010” to “111” will be described in detail later.

As shown in FIG. 2, when it is determined that the value of the extension flag field F3 of the received precharge command is “000” or “001” (S15: YES), the semiconductor memory device 120 determines whether the value of the extension flag field F3 is “000” (S20).

When it is determined that the value of the extension flag field F3 is “000” (S20: YES), the semiconductor memory device 120 performs precharging only on the bank specified in the bank address field F2 (S25).

When it is determined that the value of the extension flag field F3 is not “000” (S20: NO), the value of the extension flag field F3 is “001”, and the semiconductor memory device 120 performs precharging on all banks (S30).

In S15, when it is determined that the value of the extension flag field F3 of the received precharge command is not “000” or “001” (S15: NO), that is, when it is any of “010” to “111”, the semiconductor memory device 120 performs a precharge on the bank specified in the bank address field F2 (hereinafter also referred to as the “first bank”) (S35).

The semiconductor memory device 120 performs precharge on the second bank with a delay specified by the extension flag field F3 (S40). In this embodiment, the “second bank” refers to a bank defined by a bank address obtained by inverting a predetermined bit, which is one bit in the bit string (bits b4 to b7) that defines the bank group. In this embodiment, the “bit to be inverted” is bit b7, which is the most significant bit in the bank address field F2. Therefore, for example, when the bank address field F2 is “0000”, the first bank is the bank B0 and the second bank is the bank indicated by “1000”, that is, the bank B7. For example, when the value of the bank address field F2 is “0111” and the value of the extension flag field F3 is “111”, precharging on the bank B6 is immediately executed as the first bank, and then, five clock cycles later, precharging on the bank B15 (1111) is executed as the second bank.

After S25, S30 or S40 is completed, the precharge process ends. As described above, when one precharge command is received, depending on the value specified in the extension flag field F3, it is possible to precharge two banks. Therefore, compared to a configuration that requires sending and receiving precharge commands specifying each bank, the issuance of precharge commands is suppressed, enabling efficient use of the command bus 20.

### A3. Refresh Process

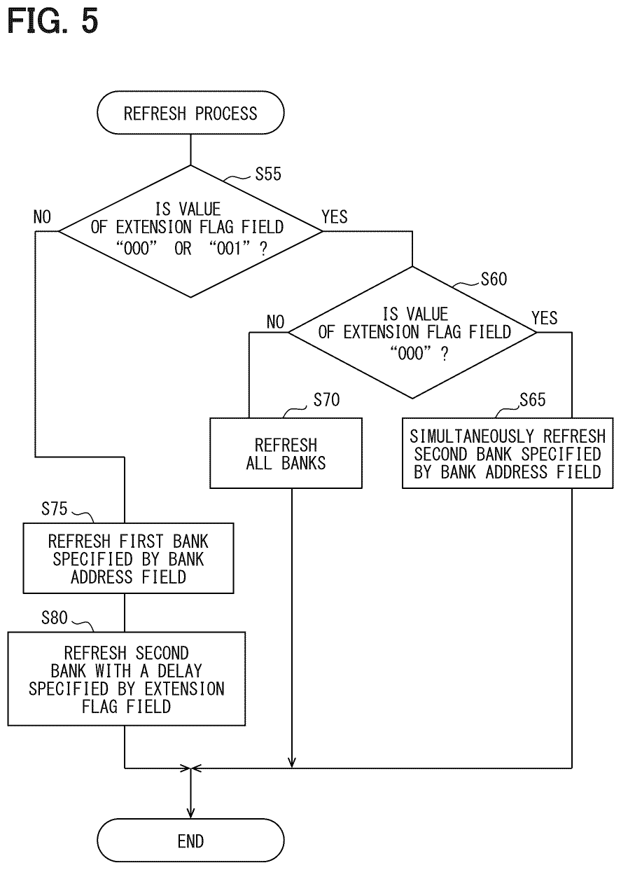

The refresh process shown in FIG. 5 is set for executing a refresh in the semiconductor memory device 120, and is executed when a refresh command is received from the memory controller 110.

The semiconductor memory device 120 determines whether the value of the extension flag field of the received refresh command is “000” or “001” (S55).

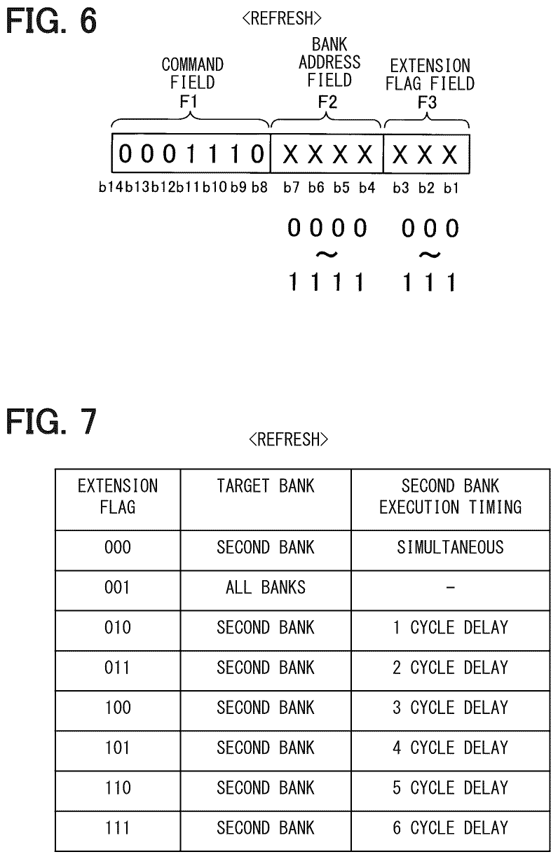

As shown in FIG. 6, the refresh command of this embodiment has a format similar to that of the precharge command. Specifically, the refresh command includes a command field F1, a bank address field F2, and an extension flag field F3. The command field F1 indicates the type of command, and is made up of a total of seven bits, e.g., bits b8 to b14. “0001110” shown in FIG. 6 indicates a refresh command. The bank address field F2 is the same as the bank address field F2 of the precharge command.

The extension flag field F3 is the same as the extension flag field F3 of the precharge command in that it consists of three bits, e.g., bits b1 to b3. However, the contents indicated therein are different from those of the extension flag field F3 of the precharge command.

The extension flag field F3 of the refresh command indicates the number of banks to be refreshed and a time difference between two banks when the two banks are refreshed with the time difference. More specifically, the extension flag field F3 specifies (i) refreshing all banks or refreshing two banks that belong to different bank groups, and (ii) the execution timing of the second bank relative to the first bank when refreshing two banks.

FIG. 7 shows a specific example of setting the extension flag field F3 in the refresh command. The following explains the settings for each value from “000” to “111.”

“000” indicates that there are two banks to be refreshed, specifically, the bank specified in the bank address field F2 (first bank) and the bank obtained by inverting the inversion target bit (second bank). The relative processing timing in (ii) indicates that the processing is simultaneous, that is, that two banks are precharged simultaneously.

“001” indicates that all banks are to be refreshed, and the bank address specified in the bank address field F2 is invalid.

“010” indicates that there are two banks to be refreshed, and the relative processing timing in (ii) is delayed by one cycle from the refresh execution of the first bank.

“011” indicates that there are two banks to be refreshed, and the relative processing timing in (ii) is delayed by two cycles from the refresh execution of the first bank.

“100” indicates that there are two banks to be refreshed, and the relative processing timing in (ii) is delayed by three cycles from the refresh execution of the first bank.

“101” indicates that there are two banks to be refreshed, and the relative processing timing in (ii) is delayed by four cycles from the refresh execution of the first bank.

“110” indicates that there are two banks to be refreshed, and the relative processing timing in (ii) is delayed by five cycles from the refresh execution of the first bank.

“111” indicates that there are two banks to be refreshed, and the relative processing timing in (ii) is delayed by six cycles from the refresh execution of the first bank.

When the extension flag field F3 is “010” to “111”, the two banks to be refreshed are the same as the first bank and the second bank in the precharge command. The bits b1 to b3 of the extension flag field F3 of the refresh command have the same meaning as the least significant three bits in the refresh command in the conventional LPDDR5. In other words, conventionally, when the lowest three bits are “000”, this meant that the first bank and the second bank specified in the bank address, a total of two banks, are to be refreshed simultaneously. Also, when the lowest three bits are “001”, it means that all banks are to be refreshed. Therefore, the purpose of using the least significant three bits is the same as in the previous system, and therefore compatibility is maintained.

As shown in FIG. 5, when it is determined that the value of the extension flag field F3 of the received refresh command is “000” or “001” (S55: YES), the semiconductor memory device 120 determines whether the value of the extension flag field F3 is “000” (S60).

When it is determined that the value of the extension flag field F3 is “000” (S60: YES), the semiconductor memory device 120 performs a refresh on the first bank and the second bank specified in the bank address field F2 (S65).

When it is determined that the value of the extension flag field F3 is not “000” (S60: NO), the value of the extension flag field F3 is “001”, and the semiconductor memory device 120 performs refresh on all banks (S70).

In S55, when it is determined that the value of the extension flag field F3 of the received precharge command is not “000” or “001” (S55: NO), that is, when it is any of “010” to “111”, the semiconductor memory device 120 performs a refresh on the first bank specified in the bank address field F2 (S75).

The semiconductor memory device 120 performs a refresh on the second bank with a delay specified by the extension flag field F3 (S80).

After S65, S70 or S80 is completed, the refresh process ends. As described above, when one refresh command is received, depending on the value specified in the extension flag field F3, it is possible to perform refresh of two banks. Therefore, compared to a configuration that requires sending and receiving refresh commands specifying each bank, the issuance of refresh commands is suppressed, enabling more efficient use of the command bus 20.

### A4. Example of Operation

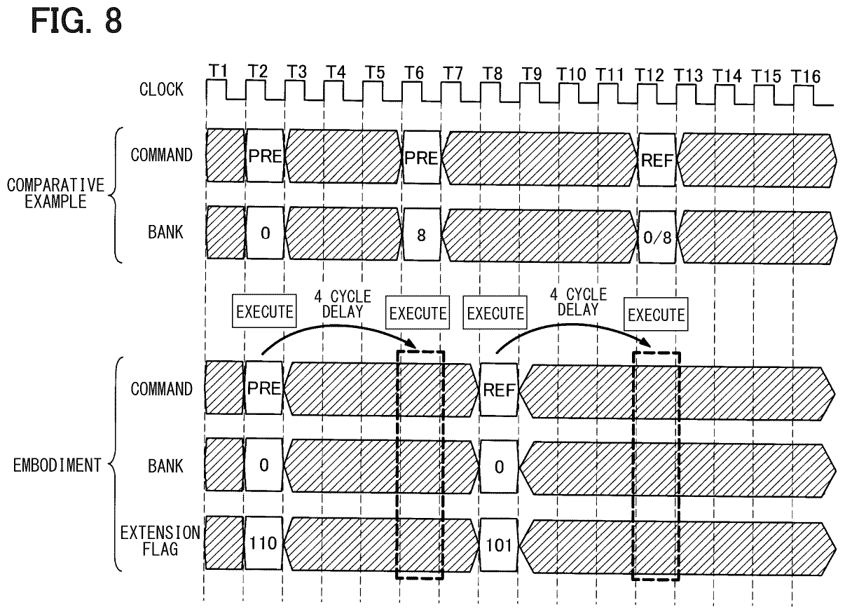

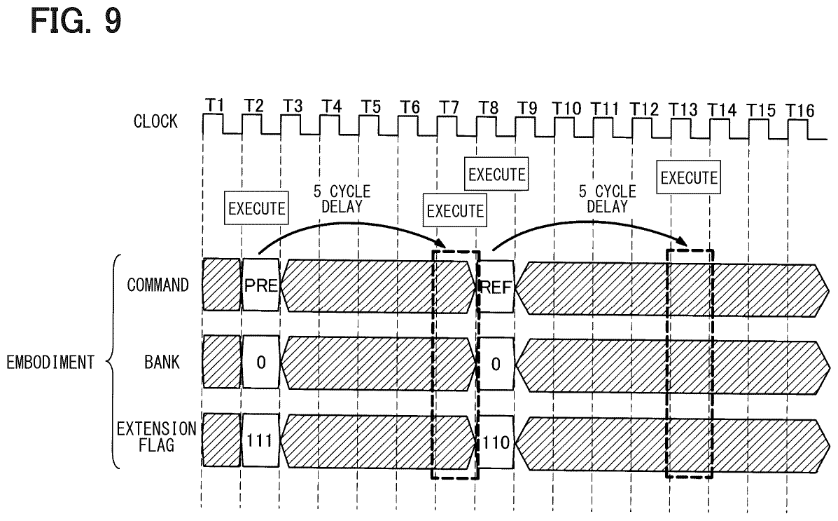

An example of operation when the precharge process and refresh process are executed will be described with reference to FIGS. 8 and 9. In FIG. 8, the upper timing chart shows the operation in a comparative example, and the lower timing chart shows the operation in the first embodiment.

In the comparative example shown in the upper part of FIG. 8, for example, to perform precharging and refreshing on the bank B0 and the bank B7, the memory controller 110 issues a precharge command (PRE) specifying the bank B0 (0000) within a period T2. The period T2 is, for example, timing when tRP has elapsed since the previous precharge on the bank B0. Furthermore, in a period T6, the memory controller 110 issues a precharge command specifying the bank B7 (1000). The period T6 is, for example, timing when tRP has elapsed since the previous precharge on the bank B7. Thereafter, the memory controller 110 attempts to issue a refresh command (REF) targeting the two banks B0 and B7. However, for example, when “6 cycles” is set as the minimum period from the issuance of precharge command until a refresh command can be issued, the refresh command for the two banks B0 and B7 is finally issued in a period T12, which is six cycles later than the period T6. The period T6 is the timing for the bank B7, for which the precharge command was issued at the later timing, of the two banks B0 and B7.

In contrast to this, in this embodiment shown in the lower part of FIG. 8, in a period T2, a bank 0 (0000) is specified in the bank address field F2 and a precharge command (PRE) with an extension flag of “110” is issued. In this case, precharging is immediately performed on the bank B0. Thereafter, in a period T6 which is delayed by four cycles from the period T2, precharging is performed on the bank B7 (1000). A refresh command (REF) specifying the bank 0 (0000) with an extension flag of “101” is issued in a period T8 delayed by six cycles from the period T2 in which the last precharge command was issued. In this case, a refresh is immediately executed on the bank B0. Thereafter, in a period T12 which is delayed by four cycles from the period T8, a refresh is executed on the bank B7.

As described above, as is clear from the comparison between the comparative example and this embodiment, the issuance of precharge commands is suppressed in this embodiment, compared to the comparative example, when performing the same operation. Furthermore, the timing of issuing the refresh command (REF) can be made earlier than in the comparative example. Therefore, in this embodiment, compared to the comparative example, the command bus 20 can be used efficiently while ensuring the timing for issuing the refresh command or precharge command.

In the operation example shown in FIG. 9, the extension flag field F3 of the precharge command is set to “111”, and the extension flag field F3 of the refresh command is set to “110”. Therefore, in response to the precharge command issued in the period T2, the bank B0 as the first bank is precharged in the period T2, and the bank B7 as the second bank is precharged in the period T7, which is delayed by five cycles from the period T2. Furthermore, a refresh command issued in the period T8 refreshes the bank B0 as the first bank in the period T8, and then refreshes the bank B7 as the second bank in the period T13, which is delayed by five cycles from the period T7. In order to execute precharging and refreshing of the two banks B0 and B7, only two commands are issued during the periods T2 to T13. Therefore, similar to the example of operation in the lower part of FIG. 8, the command bus 20 can be used efficiently while ensuring the timing for issuing the refresh command or precharge command.

In a conventional system conforming to the LPDDR5 standard, a refresh command is issued eight times every 1 μs (microsecond) in a high temperature environment, so that the command is issued once every 125 ns (nanosecond). Furthermore, since it is necessary to issue two precharge commands for each refresh command issued, three commands are issued in 125 ns (see the upper part of FIG. 8). In contrast, in the memory system 100 of this embodiment, it is sufficient to issue one precharge command while issuing one refresh command, and the number of commands issued can be reduced to one every 125 ns. The time required to issue one command is 1.25 ns, so a command reduction effect of 1% can be obtained.

Furthermore, the row address can be changed at least every 42 ns. For this reason, in a system conforming to the conventional LPDDR5 standard, two precharge commands are issued every 42 ns. In contrast, in the memory system 100 of this embodiment, the number of precharge commands issued can be reduced to one. Therefore, 1.25 ns can be saved for every 42 ns, resulting in a command reduction effect of approximately 3%.

Furthermore, two banks can be precharged with one command, and as can be seen from a comparison between the upper part and the lower part of FIG. 8, the issuance of refresh commands can be accelerated from the period T12 to the period T8. When tREFi (refresh interval) is 125 ns, four cycles, that is, 5 ns (1.25 ns×4), can be reduced for every 125 ns, resulting in a command reduction effect of 4%.

Combining the command reduction effects, it is expected that the utilization efficiency of the command bus 20 will be improved by a maximum of approximately 8% in total.

According to the memory system 100 of the first embodiment, when a precharge command specifies that two banks are to be precharged, one precharge command (PRE) can precharge two banks, e.g., the first bank and the second bank. Therefore, the issuance of precharge commands can be suppressed to create space on the command bus 20. This allows the command bus 20 to be used efficiently while ensuring the timing for issuing the precharge command.

Furthermore, when specifying that one bank is to be precharged, the memory controller 110 specifies that the bit pattern of the extension flag field F3 of the precharge command so that the least significant three bits are 000. When specifying that all banks are to be precharged, the memory controller 110 specifies that the bit pattern of the extension flag field F3 of the precharge command so that the least significant three bits are 001. Therefore, the least significant three bits can be used in the same way as in conventional memory systems. This ensures compatibility with previous memory systems.

In addition, the extension flag field F3 of the precharge command consists of a three-bit string, and five bit patterns can be specified as relative processing timing to indicate the delay cycle from the execution of precharge on the first bank. Therefore, the five delay cycles can be flexibly set according to the usage status of the command bus 20.

Furthermore, according to the memory system 100, when a refresh command (REF) specifies that two banks are to be refreshed, two banks, e.g., the first bank and the second bank, can be refreshed with one refresh command. Therefore, the issuance of refresh command can be suppressed to create space on the command bus 20. This allows the command bus 20 to be used efficiently while ensuring the timing for issuing the refresh command.

Furthermore, when specifying that two banks are to be refreshed, the memory controller 110 specifies the bit pattern of the extension flag field F3 of the refresh command so that the least significant three bits are 000. When specifying that all banks are to be refreshed, the memory controller 110 specifies the bit pattern of the extension flag field F3 of the refresh command so that the least significant three bits are 001. Therefore, the least significant three bits can be used in the same way as in conventional memory systems. This ensures compatibility with previous memory systems.

The extension flag field of the refresh command consists of a three-bit string, and six bit patterns can be specified as relative processing timing to indicate the delay cycle from the execution of the refresh on the first bank. Therefore, the six delay cycles can be flexibly set according to the usage status of the command bus.

### Second Embodiment

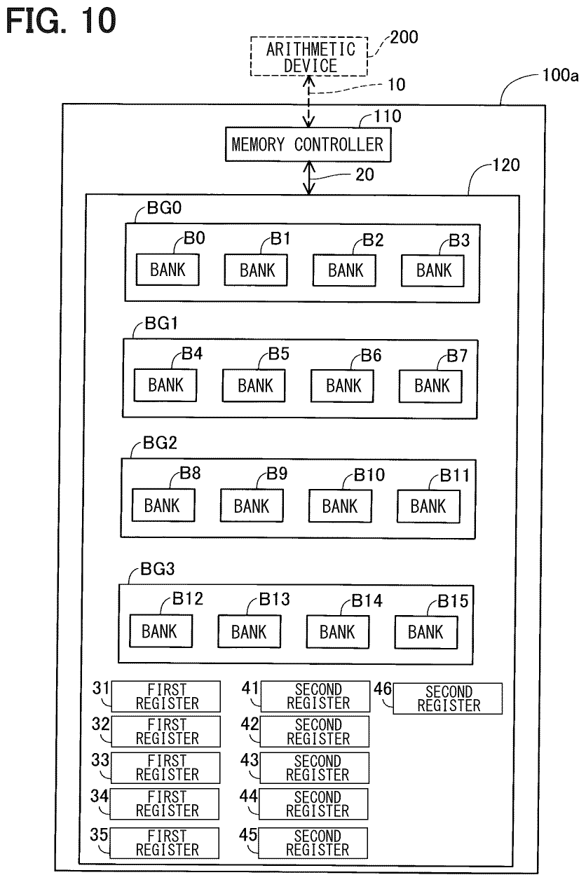

A memory system 100a of a second embodiment shown in FIG. 10 differs from the memory system 100 of the first embodiment in that it includes five first registers 31, 32, 33, 34, 35 and six second registers 41, 42, 43, 44, 45, 46. Other configurations of the memory system 100a of the second embodiment are the same as those of the memory system 100 of the first embodiment, so the same components are denoted by the same reference numerals and detailed description thereof will be omitted.

The first registers 31 to 35 have delay cycles set corresponding to the five bit patterns “011”, “100”, “101”, “110”, and “111” indicated by the extension flag field F3 of the precharge command. In addition, delay cycles are set in the second registers 41 to 46, respectively, in accordance with the six bit patterns “010”, “011”, “100”, “101”, “110”, and “111” indicated by the extension flag field F3 of the refresh command.

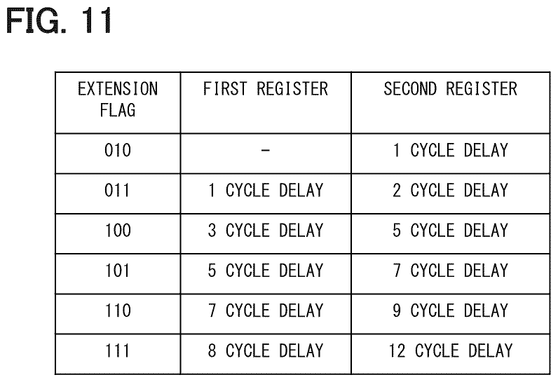

As shown in FIG. 11, in this embodiment, the following delay times are set corresponding to the five bit patterns “011”, “100”, “101”, “110”, and “111” indicated by the extension flag field F3 of the precharge command:
“011”: 1-cycle delay;
“100”: 3-cycle delay;
“101”: 5-cycle delay;
“110”: 7-cycle delay; and
“111”: 8-cycle delay.

In this embodiment, the following delay times are set in each of the second registers 41 to 46 in correspondence with the six bit patterns “010”, “011”, “100”, “101”, “110”, and “111” indicated by the extension flag field F3 of the refresh command:
“010”: 1-cycle delay;
“011”: 2-cycle delay;
“100”: 5-cycle delay;
“101”: 7-cycle delay;
“110”: 9-cycle delay; and
“111”: 12-cycle delay.

The values set in each of the first registers 31 to 35 and each of the second registers 41 to 46 are rewritable. Therefore, the user can set appropriate delay time candidates in the first registers 31 to 35 and the second registers 41 to 46 in advance, and can also change them later.

In the precharge process, in S40, the delay time set in the register corresponding to the bit pattern specified in the extension flag field F3 among the first registers 31 to 35 is read out, and the precharge of the second bank is executed after the delay time from the execution of the precharge on the first bank.

Similarly, in the refresh process, in S80, the delay time set in the register corresponding to the bit pattern specified in the extension flag field F3 among the second registers 41 to 46 is read out, and the refresh of the second bank is executed after the refresh of the first bank by the delay time.

The memory system 100a of the second embodiment has the same effects as the memory system 100 of the first embodiment. In addition, when the semiconductor memory device 120 performs a precharge on the second bank, it reads the set delay cycle from the first registers 31 to 35 corresponding to the bit pattern specified by the extension flag field F3, and performs a precharge on the second bank at a timing delayed by the delay cycle from the execution of the precharge on the first bank. Therefore, by adjusting the delay cycle set in the first registers 31 to 35, the execution timing of the precharge on the second bank can be adjusted.

Similarly, when the semiconductor memory device 120 performs a refresh on the second bank, it reads the set delay cycle from the second registers 41 to 46 corresponding to the bit pattern specified by the extension flag field F3, and performs the refresh of the second bank at a timing that is delayed by the delay cycle from the execution of the refresh on the first bank. Therefore, by adjusting the delay cycle set in the second registers 41 to 46, the execution timing of the refresh on the second bank can be adjusted.

### Other Embodiments

(C1) In each embodiment, the bit to be inverted is the most significant bit (bit b7) of the bank address field F2, but the present disclosure is not limited to this. The bit to be inverted may be a predetermined bit in a bit string that defines a bank group in the bank address section.

(C2) In each embodiment, the bits b1 to b3 of the extension flag field F3 of the precharge command and the refresh command have the same meaning as the least significant three bits of the refresh command in the conventional LPDDR5, but the present disclosure is not limited to this. The data formats of the precharge commands and the refresh commands of the present disclosure may be entirely different from those of the conventional precharge commands and refresh commands. In this configuration, the extension flag field F3 is not limited to three bits and may be configured with a string of any number of bits. Also, the extension flag field F3 does not have to include the least significant bit. Furthermore, the command field F1 and the bank address field F2 may also be configured with bit strings having a number of bits different from the number of bits in each embodiment.

(C3) In each embodiment, the present disclosure may be applied to only one of the precharge command and the refresh command, and the other may be handled by using conventional data format and be processed according to conventional rules. For example, a precharge command may be specified to precharge only one bank or all banks, and a refresh command may be specified to refresh two banks with a time lag. Alternatively, conversely, the precharge command may be specified to precharge two banks with a time lag, and the refresh command may be specified to refresh two banks simultaneously or all banks simultaneously.

(C4) Each embodiment is merely an example and can be modified in various ways. For example, the number of bank groups is not limited to four and may be any number. Furthermore, the number of banks included in each bank group is not limited to four and may be any number.

The present disclosure should not be limited to the embodiments described above, and various other embodiments may be implemented without departing from the scope of the present disclosure. For example, the technical features in each embodiment corresponding to the technical features in the form described in the summary may be used to solve some or all of the above-described problems, or to provide one of the above-described effects. In order to achieve a part or all, replacement or combination can be appropriately performed. Also, some of the technical features may be omitted as appropriate.

An entity (hereinafter referred to as “controller”) that performs the precharge and refresh processes described in the present disclosure and the method thereof may be realized by a dedicated computer provided by configuring a processor and memory that are programmed to perform one or more functions embodied in a computer program. Alternatively, the controller and the like and the method thereof described in the present disclosure may be achieved by a dedicated computer provided by configuring a processor with one or more dedicated hardware logic circuits. Alternatively, the controller and the like and the method thereof described in the present disclosure may be achieved by one or more dedicated computers configured by a combination of a processor and a memory programmed to execute one or more functions and a processor configured by one or more hardware logic circuits. The computer programs may be stored, as instructions to be executed by a computer, in a tangible non-transitory computer-readable medium.

What is claimed is:

1. A memory system comprising:
a semiconductor memory device having a plurality of bank groups; and
a memory controller configured to issue a command in response to an access request to the semiconductor memory device from an arithmetic device that accesses the semiconductor memory device, wherein the memory controller is configured to issue a precharge command to the semiconductor memory device, the precharge command including:
an extension flag field which is a bit string specifying
(i) one of a precharging of one bank, a precharging of all banks, or precharging of two banks that belong to different bank groups, and
(ii) a relative processing timing of a second bank relative to a first bank when the first bank and the second bank are precharged; and
a bank address field which is a bit string that specifies a bank address of a bank to be precharged,
the semiconductor memory device is configured to execute, when the precharge command specifies the precharging of two banks that belong to different bank groups,
a precharge on a first bank specified by the bank address field, and
a precharge on a second bank at the relative processing timing specified by the extension flag field, and
the second bank is specified by a bank address obtained by inverting an inversion target bit of the bank address field, the inversion target bit being a predetermined one bit in the bit string that specifies a bank group.

2. The memory system according to claim 1, wherein
the extension flag field includes the least significant three bits in a data format of the precharge command,
the memory controller specifies, when specifying that one bank is to be precharged, a bit pattern of the extension flag field, so that the least significant three bits are 000, and
the memory controller specifies, when specifying that all banks are to be precharged, a bit pattern of the extension flag field, so that the least significant three bits are 001.

3. The memory system according to claim 2, wherein
the extension flag field is made up of a 3-bit string, and
five bit patterns are to be specified to indicate a delay cycle from execution of the precharge on the first bank, as the relative processing timing.

4. The memory system according to claim 3, further comprising five registers, in which each delay cycle is set, corresponding to the five bit patterns respectively, wherein
when the semiconductor memory device executes the precharge on the second bank, the semiconductor memory device is configured to
read the delay cycle from the register corresponding to the bit pattern specified by the extension flag field, and
execute the precharge on the second bank at a timing delayed by the delay cycle from execution of the precharge on the first bank.

5. A memory system comprising:
a semiconductor memory device having a plurality of bank groups; and
a memory controller configured to issue a command in response to an access request to the semiconductor memory device from an arithmetic device that accesses the semiconductor memory device, wherein
the memory controller is configured to issue, to the semiconductor memory device, a refresh command including:
an extension flag field which is a bit string specifying
(i) one of a refreshing of all banks or a refreshing of two banks that belong to different bank groups, and
(ii) a relative processing timing of a second bank relative to a first bank when the first bank and the second bank are refleshed; and
a bank address field which is a bit string that specifies a bank address of a bank to be refreshed,
the semiconductor memory device is configured to execute, when the refresh command specifies that two banks are to be refreshed,
a refresh on a first bank determined by the bank address field, and
a refresh on a second bank at the relative processing timing specified by the extension flag field, and
the second bank is specified by a bank address obtained by inverting an inversion target bit of the bank address field, the inversion target bit being a predetermined one bit in the bit string that specifies a bank group.

6. The memory system according to claim 5, wherein
the extension flag field includes the least significant three bits in a data format of the refresh command,
the memory controller is configured to specify a bit pattern of the extension flag field, when specifying that two banks are to be refreshed, so that the least significant three bits are 000, and
the memory controller is configured to specify a bit pattern of the extension flag field, when specifying that all banks are to be refreshed, so that the least significant three bits are 001.

7. The memory system according to claim 6, wherein
the extension flag field is made up of a 3-bit string, and
six bit patterns are to be specified to indicate a delay cycle from execution of the refresh on the first bank, as the relative processing timing.

8. The memory system according to claim 7, further comprising six registers, in which each delay cycle is set, corresponding to the six bit patterns respectively, wherein
when the semiconductor memory device executes the refresh on the second bank, the semiconductor memory device is configured to
read the delay cycle from the register corresponding to the bit pattern specified by the extension flag field, and
execute the refresh on the second bank at a timing delayed by the delay cycle from execution of the refresh on the first bank.
